(19) United States
(12) Patent Application Publication
(10) Pub. No.: US 2015/0301972 A1
(43) Pub. Date: Oct. 22, 2015

(54) MODULE SUPPORTING HOT PLUG, BACKPLANE, SYSTEM AND METHOD FOR DETERMINING CONNECTION THEREOF

(71) Applicants: Wei LIU, Hangzhou, Zhejiang (CN); Jincheng LI, Hangzhou, Zhejiang (CN); Axel LOHBECK, Hangzhou, Zhejiang (CN)

(72) Inventors: Wei Liu, Hangzhou (CN); Jincheng Li, Hangzhou (CN); Axel Lohbeck, Hangzhou (CN)

(73) Assignee: ABB TECHNOLOGY LTD, Zurich (CH)

(21) Appl. No.: 14/441,928

(22) PCT Filed: Nov. 15, 2012
(86) PCT No.: PCT/CN2012/084677

§ 371 Date: May 11, 2015

(51) Int. Cl. G06F 13/40; H01R 13/641; G01R 31/04; H01R 43/26

(52) U.S. Cl. CPC G06F 13/4068; H01R 43/26; H01R 13/641; G01R 31/04

(57) ABSTRACT

Embodiments of the present invention disclose a module supporting hot plug, a backplane, a system comprising the module and the backplane, and a method for determining connection of the module with the backplane. The module may comprise a first connector comprising a first array of pins, and the backplane may comprise a second connector comprising a second array of pins corresponding to the first array of pins. A portion of the pins of the first array may be selected such that connection of the module with the backplane can be determined based on connection of the selected pins of the first array with corresponding pins of the second array. According to the embodiments of the present invention, the module will be enabled to work only after all the pins are effectively connected to the corresponding pins of the backplane. Thus, no invalid data will be transmitted to the field devices or controller. The hot plug function can be implemented without any extra components and without needing any extra operations from users.

### TECHNICAL FIELD

Embodiments of the present invention relate to the field of automatic control, and more particularly, relate to a module supporting hot plug, a backplane, a system comprising the module and the backplane, and a method for determining connection of the module with the backplane.

### BACKGROUND ART

A discrete control system (DCS) is a kind of automatic control system in which one or more computers are employed to control a plurality of control loops in a process of manufacturing and so on. In the DCS, in order to achieve the extendibility of the system, it is desired to allow one or more modules, such as an I/O module, a main control module, a data forwarding module and the like, to be added to or removed from a backplane provided in a running DCS, i.e., to achieve hot plug of modules.

The module typically comprises a connector for connecting the module to a backplane. An array of pins may be arranged on the connector of the module. Likewise, the backplane typically comprises a connector having an array of pins corresponding to the array of pins of the module. The array of pins of the module is mated with the array of pins of the backplane such that the module is connected to the backplane. Optionally, a Micro Controller Unit (MCU) may be connected to the connector of the module or to the connector of the backplane so as to control the module. In the array of pins of the module, some pins are used for powering the MCU, and others are to be used by field devices. In a process of connecting the module to the backplane, if the pins for the MCU are effectively connected to corresponding pins of the backplane while the pins for the field devices are not effectively connected to corresponding pins of the backplane, the MCU may work well, but control of the field devices get lost. Thus, invalid data may be transmitted to the field devices or to a controller. In order to avoid problems like this, it should better be ensured that the MCU knows whether all pins/as many pins as possible of the module are effectively connected to the backplane and enables the module based on a correct connection of the module.

In the prior art, special hot plug ICs or special connectors or mechanical switches are used for making it sure that power is off before the module is connected to or removed from the backplane. These prior art solutions can realize the hot plug function, but the special hot plug ICs are quite expensive and the mechanical switches require additional operations from users during hot plug.

### SUMMARY OF INVENTION

In view of the foregoing, one or more of the objectives of embodiments of the present invention is to propose a new hot plug solution so as to solve or at least partially mitigate at least part of problems in the prior art.

According to a first aspect of embodiments of the present invention, there is provided a module supporting hot plug. The module can comprise a connector for connecting the module to a backplane. The connector comprises an array of pins, wherein a portion of the pins of the array are selected such that connection of the module with the backplane can be determined based on connection of the selected pins with the backplane.

According to an exemplary embodiment, the selected pins are configured such that once the selected pins are effectively connected to the backplane, the selected pins will come to be connected in series with each other, and a signal for indicating an effective connection of the selected pins with the backplane can be detected at one terminal of the serial connection of the selected pins, whereby an effective connection of the module with the backplane can be determined based on the signal.

According to an exemplary embodiment, the selected pins can comprise at least three pins which are located at or in close proximity to a periphery of the connector.

According to an exemplary embodiment, the selected pins can comprise at least four pins which are located at or in close proximity to an upper left corner, a lower left corner, a lower right corner and an upper right corner of the array, respectively. According to an exemplary embodiment, the selected pins can further comprise at least one pin which is located between the pins which are located at or in close proximity to the upper left and lower left corners, or between the pins which are located at or in close proximity to the lower right and upper right corners.

According to an exemplary embodiment, the module can further comprise a Micro Controller Unit (MCU) connected to the connector and configured to determine, based on the determined connection of the module with the backplane, whether the module should be enabled.

According to an exemplary embodiment, one of the selected pins is connected to a power source via a first resister and to the MCU, and another one of the selected pins is connected to the ground.

According to an exemplary embodiment, one of the selected pins is connected to the ground via a second resister and to the MCU, and another one of the selected pins is connected to a power source.

According to a second aspect of embodiments of the present invention, there is provided a backplane. The backplane can comprise a first connector being configured to be used in conjunction with a second connector of a module supporting hot plug. The second connector comprises an array of pins. The first connector comprises an array of pins corresponding to the array of pins of the second connector. A portion of the pins of the array of the first connector can be selected such that connection of the module with the backplane can be determined based on connection of the selected pins of the first connector with corresponding pins of the second connector.

According to an exemplary embodiment, the selected pins are configured such that once the selected pins are effectively connected to the corresponding pins of the second connector, the selected pins will come to be connected in series with each other, and a signal for indicating an effective connection of the selected pins with the corresponding pins of the second connector can be detected at one terminal of the serial connection of the selected pins, whereby an effective connection of the module with the backplane can be determined based on the signal.

According to an exemplary embodiment, the selected pins can comprise at least three pins which are located at or in close proximity to a periphery of the first connector.

According to an exemplary embodiment, the selected pins can comprise at least four pins which are located at or in close proximity to an upper left corner, a lower left corner, a lower right corner and an upper right corner of the array of the first connector, respectively. According to an exemplary embodiment, the selected pins can further comprise at least one pin which is located between the pins which are located at or in close proximity to the upper left and lower left corners, or between the pins which are located at or in close proximity to the lower right and upper right corners.

According to an exemplary embodiment, the backplane can further comprise a Micro Controller Unit (MCU) connected to the first connector.

According to an exemplary embodiment, one of the selected pins is connected to a power source via a third resister and to the MCU, and another one of the selected pins is connected to the ground.

According to an exemplary embodiment, one of the selected pins is connected to the ground via a fourth resister and to the MCU, and another one of the selected pins is connected to a power source.

According to a third aspect of embodiments of the present invention, there is provided a method for determining connection of a module with a backplane. The module can comprise a first connector comprising an array of pins, and the backplane can comprise a second connector comprising an array of pins corresponding to the array of pins of the first connector. The method can comprise selecting a portion of the pins of the first connector, connecting the first connector to the second connector, detecting whether the selected pins are effectively connected to corresponding pins of the second connector, and determining whether the module is effectively connected to the backplane based on the detecting.

According to an exemplary embodiment, the method can further comprise: configuring the selected pins such that once the selected pins are effectively connected to the backplane, the selected pins will come to be connected in series with each other, and a signal for indicating an effective connection of the selected pins with the backplane is detected at one terminal of the serial connection of the selected pins, whereby an effective connection of the module with the backplane is determined based on the signal.

According to an exemplary embodiment, selecting a portion of the pins of the first connector comprises selecting at least three pins which are located at or in close proximity to a periphery of the first connector.

According to an exemplary embodiment, selecting a portion of the pins of the first connector comprises selecting at least four pins which are located at or in close proximity to an upper left corner, a lower left corner, a lower right corner and an upper right corner of the first connector, respectively.

According to an exemplary embodiment, the method can further comprise: connecting one of the four selected pins to a power source via a first resister and to a MCU, connecting another one of the four selected pins to the ground, short-circuiting the remaining two of the four selected pins with each other, short-circuiting the pin of the second connector corresponding to the one of the four selected pins with the pin of the second connector corresponding to one of the remaining two of the four selected pins, and short-circuiting the pin of the second connector corresponding to the another one of the four selected pins with the pin of the second connector corresponding to the other of the remaining two of the four selected pins. Detecting whether the four selected pins are effectively connected to the corresponding pins comprises detecting a voltage at the one of the four selected pins with the MCU. Determining whether the module is effectively connected to the backplane based on the detecting comprises determining the module is effectively connected to the backplane if the detected voltage is equal to zero, or determining the module is not effectively connected to the backplane if the detected voltage is equal to the voltage supplied by the power source.

According to an exemplary embodiment, the method can further comprise: connecting one of the four selected pins to the ground via a second resister and to a MCU, connecting another one of the four selected pins to a power source, short-circuiting the remaining two of the four selected pins with each other, short-circuiting the pin of the second connector corresponding to the one of the four selected pins with the pin of the second connector corresponding to one of the remaining two of the four selected pins, short-circuiting the pin of the second connector corresponding to the another one of the four selected pins with the other of the remaining two of the four selected pins. Detecting whether the four selected pins are effectively connected to the corresponding pins of the second connector comprises detecting a voltage at the one of the four selected pins with the MCU. Determining whether the module is effectively connected to the backplane based on the detecting comprises determining the module is effectively connected to the backplane if the detected voltage is equal to the voltage supplied by the power source, or determining the module is not effectively connected to the backplane if the detected voltage is equal to zero.

According to a fourth aspect of embodiments of the present invention, there is provided a system comprising a module supporting hot plug and a backplane. The module comprises a first connector comprising a first array of pins, and the backplane comprises a second connector comprising a second array of pins corresponding to the first array of pins. A portion of the pins of the first array are selected such that connection of the module with the backplane can be determined based on connection of the selected pins of the first array with corresponding pins of the second array.

According to an exemplary embodiment, the selected pins of the first array and corresponding pins of the second array can be configured such that once the selected pins of the first array are effectively connected to the corresponding pins of the second array, the selected pins will come to be connected in series with each other, and a signal for indicating an effective connection of the selected pins with the corresponding pins of the second array can be detected at one terminal of the serial connection of the selected pins, whereby an effective connection of the module with the backplane can be determined based on the signal.

According to an exemplary embodiment, the selected pins can comprise at least three pins which are located at or in close proximity to a periphery of the first array.

According to an exemplary embodiment, the selected pins can comprise at least four pins which are located at or in close proximity to an upper left corner, a lower left corner, a lower right corner and an upper right corner of the first array, respectively.

According to an exemplary embodiment, the selected pins can further comprise at least one pin which is located between the pins which are located at or in close proximity to the upper left and lower left corners of the first array, or between the pins which are located at or in close proximity to the lower right and upper right corners of the first array.

According to an exemplary embodiment, the system can further comprise a Micro Controller Unit (MCU) connected to the first connector and configured to determine, based on the determined connection of the module with the backplane, whether the module should be enabled. In this embodiment, one of the selected pins is connected to a power source via a first resister and to the MCU, and another one of the selected pins is connected to the ground. Alternatively, one of the selected pins is connected to the ground via a second resister and to the MCU, and another one of the selected pins is connected to a power source.

According to an exemplary embodiment, the system can further comprise a Micro Controller Unit (MCU) connected to the second connector. In this embodiment, one of the pins of the second array corresponding to the selected pins of the first array is connected to a power source via a third resister and to the MCU, and another one of the pins of the second array corresponding to the selected pins of the first array is connected to the ground. Alternatively, one of the pins of the second array corresponding to the selected pins of the first array is connected to the ground via a fourth resister and to the MCU, and another one of the pins of the second array corresponding to the selected pins of the first array is connected to a power source.

According to an exemplary embodiment, the selected pins comprise a first pair of pins and a second pair of pins and the corresponding pins of the second array comprise a third pair of pins and a fourth pair of pins corresponding to the first pair of pins and the second pair of pins respectively. One of the first pair of pins is short-circuited with the other of the first pair of pins while one of the third pair of pins is short-circuited with one of the fourth pair of pins and the other one of the third pair of pins is short-circuited with the other one of the fourth pair of pins.

According to the solutions of the embodiments of the present invention, the module will be enabled to work only after all the pins are effectively connected to the corresponding pins of the backplane. Thus, no invalid data will be transmitted to the field devices or controller. With the solutions of the embodiments of the present invention, the hot plug function can be implemented without any extra components and without needing any extra operations from users.

Other features and advantages of the embodiments of the present invention will also be apparent from the following description of specific embodiments when read in conjunction with the accompanying drawings, which illustrate, by way of example, the principles of embodiments of the invention.

### BRIEF DESCRIPTION OF DRAWINGS

Embodiments of the invention are presented in the sense of examples and their advantages are explained in greater detail below, with reference to the accompanying drawings, wherein

FIG. 1 schematically illustrates a diagram of a module supporting hot plug according to a first embodiment of the first aspect of embodiments of the present invention;

FIG. 2 schematically illustrates a diagram of a module supporting hot plug according to an example of a second embodiment of the first aspect of embodiments of the present invention;

FIG. 3 schematically illustrates a diagram of a module supporting hot plug according to anther example of the second embodiment of the first aspect of embodiments of the present invention;

FIG. 4 schematically illustrates a diagram of a module supporting hot plug according to a yet another example of the second embodiment of the first aspect of embodiments of the present invention;

FIG. 5 schematically illustrates a diagram of a module supporting hot plug according to a third embodiment of the first aspect of embodiments of the present invention;

FIG. 6 schematically illustrates a diagram of a module supporting hot plug according to an example of a fourth embodiment of the first aspect of embodiments of the present invention;

FIG. 7 schematically illustrates a diagram of a module supporting hot plug according to an example of a fifth embodiment of the first aspect of embodiments of the present invention;

FIG. 8 schematically illustrates a diagram of a backplane according to a first embodiment of the second aspect of embodiments of the present invention;

FIG. 9 schematically illustrates a diagram of a backplane according to an example of a second embodiment of the second aspect of embodiments of the present invention;

FIG. 10 schematically illustrates a diagram of a backplane according to anther example of the second embodiment of the second aspect of embodiments of the present invention;

FIG. 11 schematically illustrates a diagram of a backplane according to a yet another example of the second embodiment of the second aspect of embodiments of the present invention;

FIG. 12 schematically illustrates a diagram of a backplane according to a third embodiment of the second aspect of embodiments of the present invention;

FIG. 13 schematically illustrates a diagram of a backplane according to an example of a fourth embodiment of the second aspect of embodiments of the present invention;

FIG. 14 schematically illustrates a diagram of a backplane according to an example of a fifth embodiment of the second aspect of embodiments of the present invention;

FIG. 15 illustrates a flow chart of a method for determining connection of a module with a backplane according to an embodiment of the present invention; and

FIG. 16 illustrates a diagram of the module supporting hot plug as shown in FIG. 6 and a backplane to be used in conjunction therewith.

### DETAILED DESCRIPTION OF EMBODIMENTS

It should be appreciated that, while this specification contains many specific implementation details, they should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

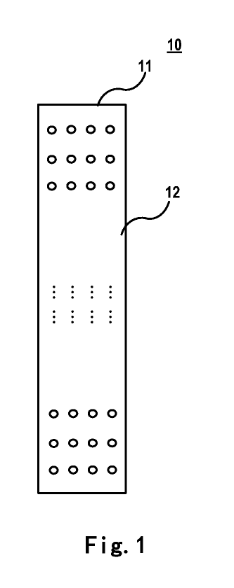

In a first aspect of embodiments of the present invention, there is provided a module supporting hot plug. Hereinafter, reference will be made to FIGS. 1 to 7 to describe the module supporting hot plug according to the first aspect of the embodiments of the present invention.

FIG. 1 schematically illustrates a diagram of a module supporting hot plug according to a first embodiment of the first aspect of the embodiments of the present invention. The module may be, for example, an I/O module, a main control module, a data forwarding module and the like. The backplane may be, for example, arranged in an I/O station of the DCS. The present invention may be applied to any module and backplane having a hot plug function.

As shown in FIG. 1, a module supporting hot plug 10 comprises a connector 11 for connecting the module 10 to a backplane (not shown). The connector 11 comprises an array of pins 12. The pins may be male or female ones. The array 12 may comprises m rows×n columns of pins. Although it is schematically shown in FIG. 1 that the array 12 comprises 4 columns of pins, it will be understood that the number of the column of pins may have any suitable value, such as 2, 3, etc. Likewise, the number of the row of pins may have any suitable value, such as 36. According to the embodiments of the present application a portion of the pins of the array 12 are selected such that connection of the module 10 with the backplane can be determined based on connection of the selected pins with the backplane.

In the second embodiment of the module supporting hot plug according to the present invention, the selected pins are configured such that once the selected pins are effectively connected to the backplane, the selected pins will come to be connected in series with each other, and a signal for indicating an effective connection of the selected pins with the backplane can be detected at one terminal of the serial connection of the selected pins, whereby an effective connection of the module with the backplane can be determined based on the signal.

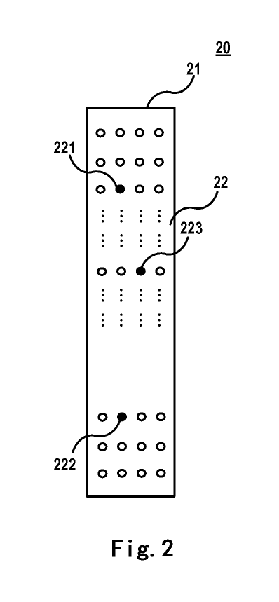

It will be noted that, for the purpose of clarity, the selected pins of the connector of the module are represented by circles filled with black “•” in FIGS. 2-7.

According to an example of the second embodiment of the module supporting hot plug, the selected pins can comprise at least three pins which are located at or in close proximity to a periphery of the connector, as schematically shown in FIG. 2. In FIG. 2, a module supporting hot plug 20 comprises a connector 21 for connecting the module 20 to a backplane (not shown). The connector 21 comprises an array of pins 22. The selected pins comprise three pins 221-223 which are located in close proximity to a periphery of the connector 21. Alternatively, the three selected pins 221-223 may be located at the periphery of the connector 21. Preferably, the three selected pins 221-223 are located at different side of the connector 21, for example, top, left and bottom respectively, or in close proximity to different side of the connecter; and/or are spaced apart from each other as far as possible.

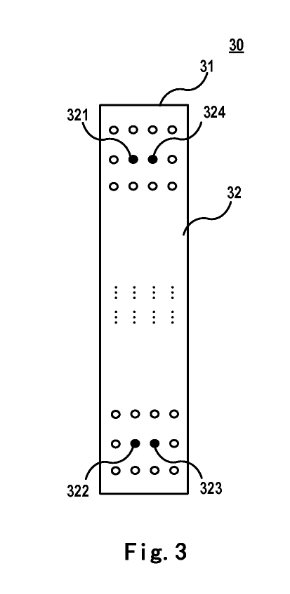

According to another example of the second embodiment of the module supporting hot plug, the selected pins comprises at least four pins which are located at or in close proximity to an upper left corner, a lower left corner, a lower right corner and an upper right corner of the array, respectively, as schematically shown in FIG. 3. In FIG. 3, a module supporting hot plug 30 comprises a connector 31 for connecting the module 30 to a backplane (not shown). The connector 31 comprises an array of pins 32. The selected pins comprise four pins 321-324 which are located in close proximity to an upper left corner, a lower left corner, a lower right corner and an upper right corner of the array 32, respectively. Alternatively, the four selected pins 321-324 may be located at an upper left corner, a lower left corner, a lower right corner and an upper right corner of the array 32, respectively.

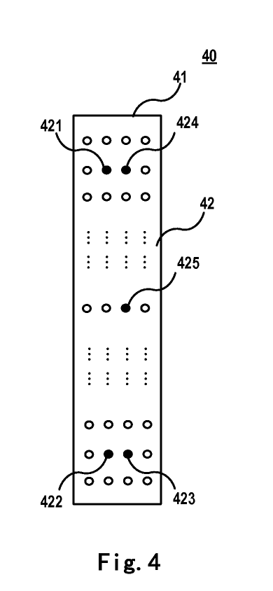

In order to improve the accuracy in determining the connection of the module with the backplane based on the connection of the selected pins with the backplane, according to yet another example of the second embodiment of the module supporting hot plug, the selected pins further comprise at least one pin which is located between the pins which are located at or in close proximity to the upper left and lower left corners, or between the pins which are located at or in close proximity to the lower right and upper right corners, as schematically shown in FIG. 4. In FIG. 4, a module supporting hot plug 40 can comprise a connector 41 for connecting the module 40 to a backplane (not shown). The connector 41 comprises an array of pins 42. Besides the four pins 421-424 which are located in close proximity to an upper left corner, a lower left corner, a lower right corner and an upper right corner of the array 42, the selected pins further comprise a pin 425 located between the pins 423 and 424. Alternatively, the pin 425 may be located between the pins 421 and 422.

In a third embodiment of the module supporting hot plug according to the present invention, the module further comprises a MCU connected to the connector. In this embodiment, the selected pins of the connector are configured such that once the selected pins are effectively connected to the backplane, the selected pins will come to be connected in series with each other, and a signal for indicating an effective connection of the selected pins with the backplane can be detected at one terminal of the serial connection of the selected pins, whereby an effective connection of the module with the backplane can be determined based on the signal. The MCU is configured to determine, based on the determined effective connection of the module with the backplane, the module should be enabled. Otherwise, the MCU will determine the module should not be enabled.

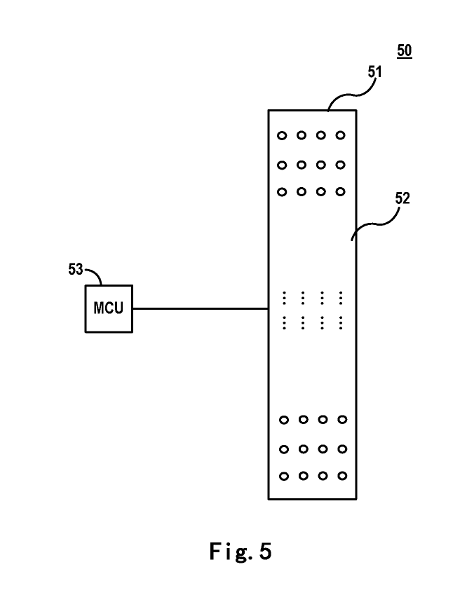

FIG. 5 schematically illustrates a diagram of a module supporting hot plug according to the third embodiment. In FIG. 5, a module supporting hot plug 50 can comprise a connector 51 for connecting the module 50 to a backplane (not shown) and a MCU 53 connected to the connector 51. The connector 51 comprises an array of pins 52. The MCU 53 is configured to determine, based on the determined connection of the module 50 with the backplane, whether the module 50 should be enabled. It should be understood that the connector 51 can be implemented with any one of the connectors as shown in FIGS. 1-4.

In a fourth embodiment of the module supporting hot plug according to the present invention, the module further comprises, besides the MCU as described in the third embodiment, a power source for powering the module. In this embodiment, one of the selected pins is connected to the power source via a first resister and to the MCU, and another one of the selected pins is connected to the ground.

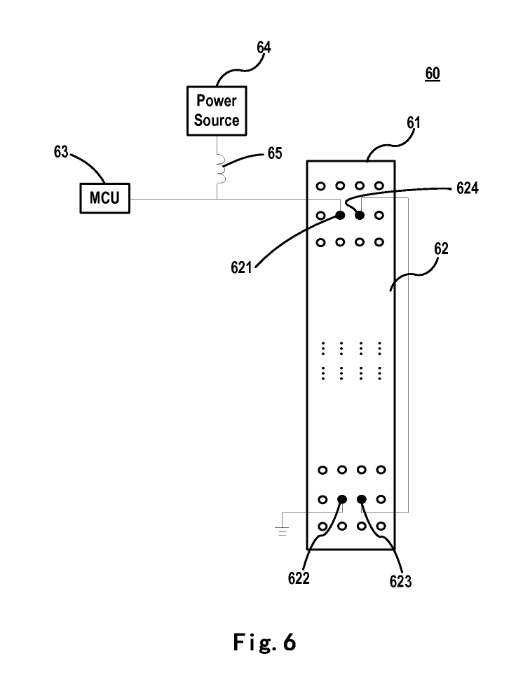

FIG. 6 schematically illustrates a diagram of a module supporting hot plug according to an example of the fourth embodiment. In FIG. 6, a module supporting hot plug 60 comprises a connector 61 for connecting the module 60 to a backplane (not shown), a MCU 63 and a power source 64. The connector 61 comprises an array of pins 62. Pins 621-624 of the array 62 are selected such that connection of the module 60 with the backplane can be determined based on connection of the selected pins 621-624 with the backplane. The pin 621 is connected to the power source 64 via a resister 65 and to the MCU 63, the pin 622 is connected to the ground and the pin 623 is short-circuited with the pin 624.

In a fifth embodiment of the module supporting hot plug according to the present invention, the module further comprises, besides the MCU as described in the third embodiment, a power source for powering the module. In this embodiment, one of the selected pins is connected to the ground via a second resister and to the MCU, and another one of the selected pins is connected to the power source.

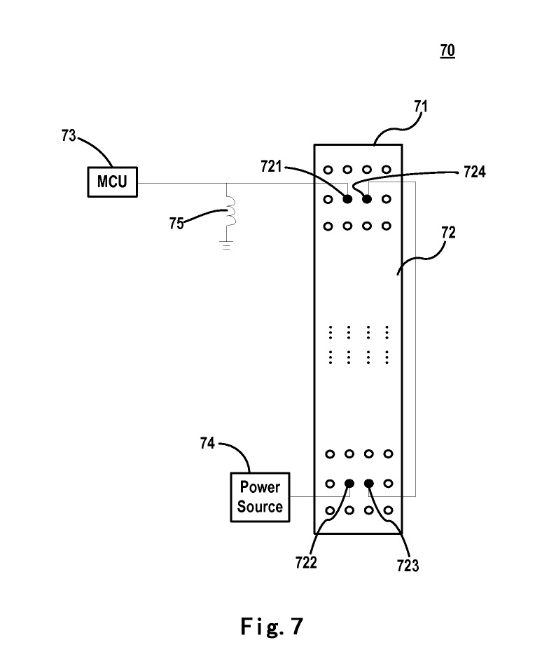

FIG. 7 schematically illustrates a diagram of a module supporting hot plug according to an example of a fifth embodiment of the first aspect of the present invention. In FIG. 7, a module supporting hot plug 70 comprises a connector 71 for connecting the module 70 to a backplane (not shown), a MCU 73 and a power source 74. The connector 71 comprises an array of pins 72. Pins 721-724 of the array 72 are selected such that connection of the module 70 with the backplane can be determined based on connection of the selected pins 721-724 with the backplane. The pin 721 is connected to the ground via a resister 75 and to the MCU 73, the pin 722 is connected to the power source 74 and the pin 723 is short-circuited with the pin 724.

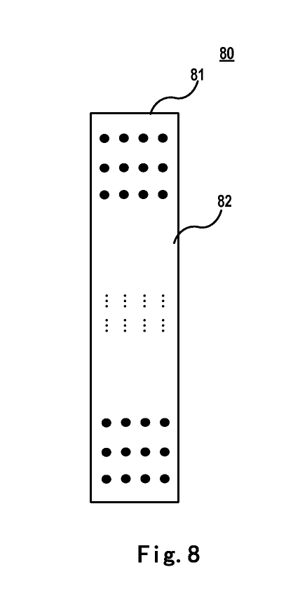

In a second aspect of embodiments of the present invention, there is provided a backplane. Hereinafter, reference will be made to FIGS. 8 to 15 to describe the backplane according to the second aspect of the present invention.

FIG. 8 schematically illustrates a diagram of a backplane according to a first embodiment of the second aspect of embodiments of the present invention. As shown in FIG. 8, a backplane 80 comprises a connector 81. The connector 81 is configured to be used in conjunction with a connector of a module supporting hot plug, such as one of the connectors as described with reference to FIGS. 1-7. As described above, the connector of the module supporting hot plug, such as the connector 11, 21, 31, 41, 51, 61 or 71 as shown in FIGS. 1-7, respectively, comprises an array of pins. The connector 81 comprises an array of pins 82 corresponding to the array of pins of the connector of the module. The pins 82 may be male or female ones. A portion of the pins of the array of the connector 81 are selected such that connection of the module with the backplane 80 can be determined based on connection of the selected pins of the connector 81 with corresponding pins of the connector of the module.

In a second embodiment of the backplane according to the present invention, the selected pins of the connector 81 are configured such that once the selected pins are effectively connected to the corresponding pins of the connector of the module, the selected pins will come to be connected in series with each other, and a signal for indicating an effective connection of the selected pins with the corresponding pins of the connector of the module can be detected at one terminal of the serial connection of the selected pins, whereby an effective connection of the module with the backplane can be determined based on the signal.

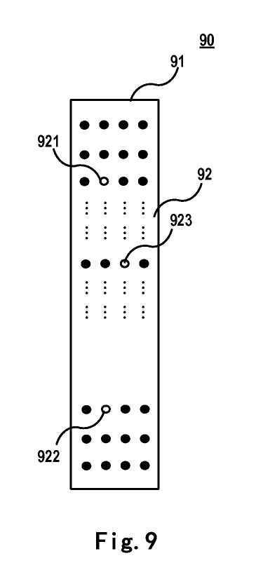

It will be noted that, for the purpose of clarity, the selected pins of the connector of the backplane are represented by circles “o” in FIGS. 9-15.

As an example of the second embodiment of the backplane, the selected pins comprises at least three pins which are located at or in close proximity to a periphery of the connector of the backplane, as schematically shown in FIG. 9. In FIG. 9, a backplane 90 comprises a connector 91 for connecting the module to the backplane 90. The module may be, for example, any one of the modules as shown in FIGS. 1-8. The connector 91 comprises an array of pins 92. The selected pins comprise three pins 921-923 which are located in close proximity to a periphery of the connector 21. Alternatively, the three selected pins 921-923 may be located at the periphery of the connector 91. Preferably, the three selected pins 921-923 are located at different side of the connector 91, for example, top, left and bottom respectively, or in close proximity to different side of the connecter; and/or are spaced apart from each other as far as possible.

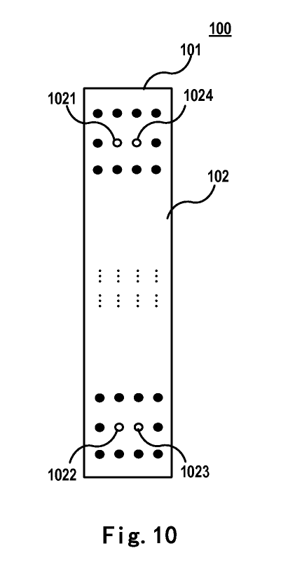

As another example of the second embodiment of the backplane, the selected pins comprises at least four pins which are located at or in close proximity to an upper left corner, a lower left corner, a lower right corner and an upper right corner of the array, respectively, as schematically shown in FIG. 10. In FIG. 10, a backplane 100 comprises a connector 101 for connecting the module to the backplane 100. The connector 101 comprises an array of pins 102. The selected pins comprise four pins 1021-1024 which are located in close proximity to an upper left corner, a lower left corner, a lower right corner and an upper right corner of the array 102, respectively. Alternatively, the four selected pins 1021-1024 may be located at an upper left corner, a lower left corner, a lower right corner and an upper right corner of the array 102, respectively. The module may be, for example, the module 30 as shown in FIG. 3.

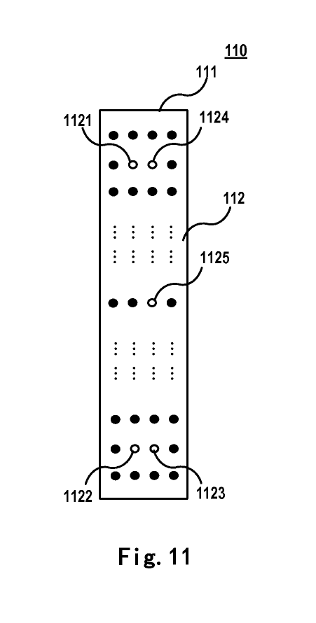

As yet another example of the second embodiment of the backplane, the selected pins can further comprise at least one pin which is located between the pins which are located at or in close proximity to the upper left and lower left corners, or between the pins which are located at or in close proximity to the lower right and upper right corners, as schematically shown in FIG. 11. In FIG. 11, a backplane 110 comprises a connector 111 for connecting the module to the backplane 110. The module may be, for example, any one of the modules as shown in FIGS. 1-8. The connector 111 comprises an array of pins 112. Besides the four pins 1121-1124 which are located in close proximity to an upper left corner, a lower left corner, a lower right corner and an upper right corner of the array 112, the selected pins also comprises a pin 1125 located between the pins 1123 and 1124. Alternatively, the pin 1125 may be located between the pins 1121 and 1122.

In a third embodiment of the backplane according to the present invention, the backplane further comprises a MCU connected to the connector of the backplane. In this embodiment, the selected pins of the connector of the backplane are configured such that once the selected pins are effectively connected to the corresponding pins of the connector of the module, the selected pins will come to be connected in series with each other, and a signal for indicating an effective connection of the selected pins with the corresponding pins of the connector of the module can be detected at one terminal of the serial connection of the selected pins, whereby an effective connection of the module with the backplane can be determined based on the signal.

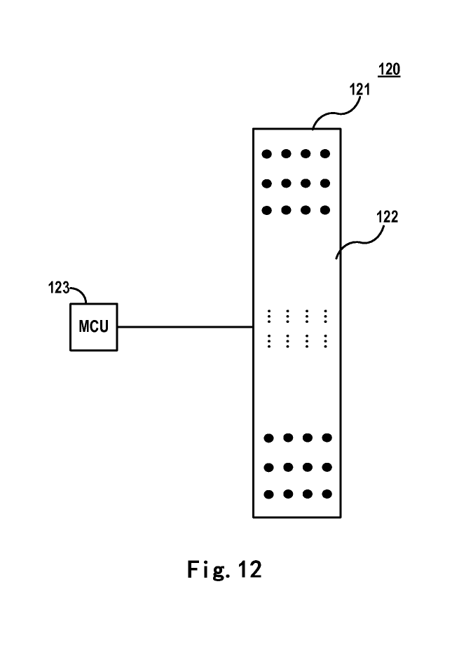

FIG. 12 schematically illustrates a diagram of a backplane according to the third embodiment. In FIG. 12, a backplane 120 comprises a connector 121 for connecting a module (not shown) to a backplane 120 and a MCU 123 connected to the connector 121. The module may be, for example, any one of the modules as shown in FIGS. 1-4. The connector 121 comprises an array of pins 122. It should be understood that the connector 121 can be implemented with any one of the connectors as shown in FIGS. 8-11.

In a fourth embodiment of the backplane according to the present invention, one of the selected pins of the connector of the backplane is connected to a power source via a third resister and to the MCU, and another one of the selected pins is connected to the ground.

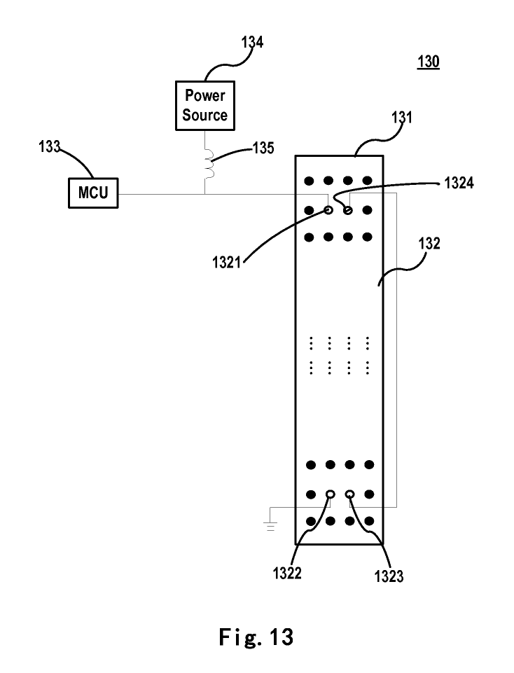

FIG. 13 schematically illustrates a diagram of a backplane according to an example of the fourth embodiment. In FIG. 13, a backplane 130 comprises a connector 131 for connecting the module (not shown) to the backplane 130, a MCU 133 and a power source 134. The module may be, for example, any one of the modules as shown in FIGS. 1-4. The connector 131 comprises an array of pins 132. Pins 1321-1324 of the array 132 are selected such that connection of the module with the backplane 130 can be determined based on connection of the selected pins 1321-1324 with corresponding pins of the connector of the module. The pin 1321 is connected to the power source 134 via a resister 135 and to the MCU 133, the pin 1322 is connected to the ground, and the pin 1323 is short-circuited with the pin 1324.

In a fifth embodiment of the backplane according to the present invention, one of the selected pins of the backplane is connected to the ground via a fourth resister and to the MCU, and another one of the selected pins is connected to a power source.

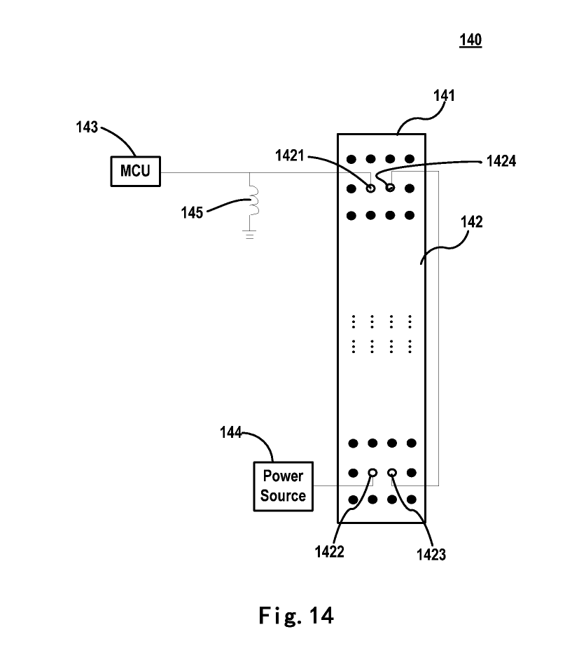

FIG. 14 schematically illustrates a diagram of a backplane according to an example of the fifth embodiment. In FIG. 14, a backplane 140 comprises a connector 141 for connecting the module (not shown) to the backplane 140, a MCU 143 and a power source 144. The module may be, for example, any one of the modules as shown in FIGS. 1-4. The connector 141 comprises an array of pins 142. Pins 1421-1424 of the array 142 are selected such that connection of the module with the backplane 140 can be determined based on connection of the selected pins 1421-1424 with corresponding pins of the connector of the module. The pin 1421 is connected to the ground via a resister 145 and to the MCU 143, the pin 1422 is connected to the power source 144, and the pin 1423 is short-circuited with the pin 1424.

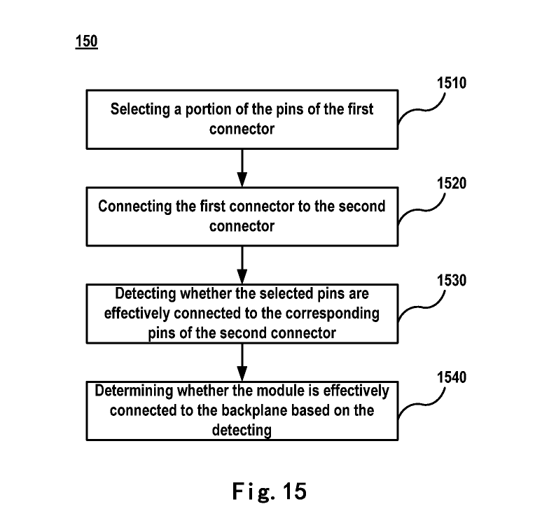

In a third aspect of the present invention, there is provided a method for determining connection of a module with a backplane. Hereinafter, reference will be made to FIG. 15 to describe the method according to the third aspect of the present invention.

In the method for determining connection of the module with the backplane according to the present invention, the module comprises a first connector comprising an array of pins, and the backplane comprises a second connector comprising an array of pins corresponding to the array of pins of the first connector. It will be understood that the module can be implemented with any one of the modules as described with reference to FIGS. 1-7, and the backplane can be implemented with any one of the backplanes as described with reference to FIGS. 8-14.

As shown in FIG. 15, a method for determining connection of a module with a backplane 1500 starts with a step 1510.

At the step 1510, a portion of the pins of the first connector is selected. For example, there are selected at least three pins which are located at or in close proximity to a periphery of the first connector, as schematically shown in FIG. 2. Alternatively, there are selected at least four pins which are located at or in close proximity to an upper left corner, a lower left corner, a lower right corner and an upper right corner of the first connector, respectively, as schematically shown in FIGS. 3 and 4.

Then, the first connector is connecting to the second connector (step 1520).

Next, at a step 1530, it is detected whether the selected pins of the first connector are effectively connected to the corresponding pins of the second connector.

Then, it is determined whether the module is effectively connected to the backplane based on the detecting (step 1540).

It should be noted that, in the present invention, the process of determining the connection of the module with the backplane based on the connection of the selected pins with the corresponding pins of the second connector goes with the following assumption. That is, once the selected pins of the first connector are effectively connected to the corresponding pins of the second connector, it could be considered that all the pins of the first connector are effectively connected to the corresponding pins of the second connector, thereby determining the module is effectively connected to the backplane.

In an embodiment of the method according to the present invention, the method further comprises configuring the selected pins such that once the selected pins are effectively connected to the backplane, the selected pins will come to be connected in series with each other, and a signal for indicating an effective connection of the selected pins with the backplane is detected at one terminal of the serial connection of the selected pins, whereby an effective connection of the module with the backplane is determined based on the signal.

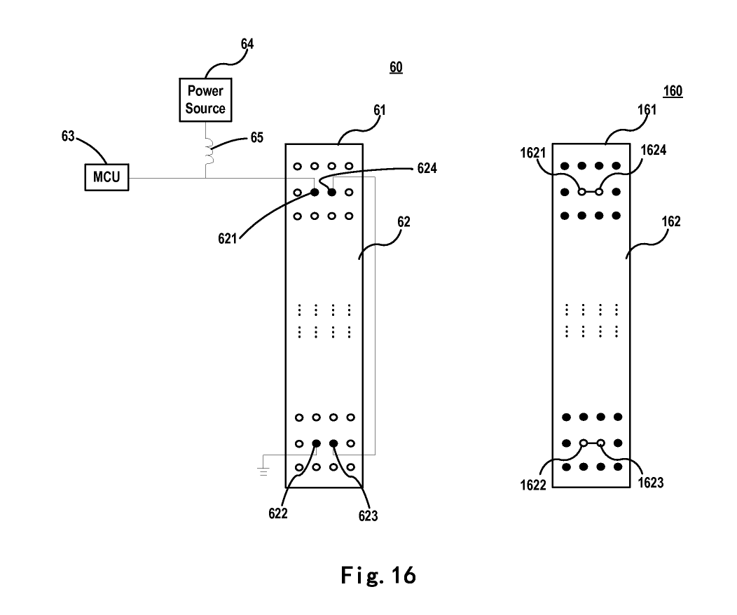

Hereinafter, reference will be made to FIG. 16 to describe a specific example according to the embodiment of the method of the present invention.

There is shown on the left of FIG. 16 the module supporting hot plug 60 as illustrated in FIG. 6, and there is shown on the right of FIG. 16 a backplane 160 to be used in conjunction with the module 60. The backplane 160 comprises a second connector 161 for connecting the module 60 to the backplane 160. The connector 161 comprises an array of pins 162. Four pins 1621-1624 are located in close proximity to an upper left corner, a lower left corner, a lower right corner and an upper right corner of the array 162, respectively, and correspond to the four pins 621-624 of the module 60.

In this example, the method further comprises connecting one of the four selected pins to a power source via a first resister and to a MCU, connecting another one of the four selected pins to the ground, and short-circuiting the remaining two of the four selected pins with each other. As shown on the left of FIG. 16, the four pins 621-624 of the module are selected. The pin 621 is connected to the power source 64 via a resister 65 and to the MCU 63, the pin 622 is connected to the ground and the pin 623 is short-circuited with the pin 624.

Further, the method comprises short-circuiting the pin of the second connector corresponding to the one of the four selected pins with the pin of the second connector corresponding to one of the remaining two of the four selected pins, and short-circuiting the pin of the second connector corresponding to the another one of the four selected pins with the pin of the second connector corresponding to the other of the remaining two of the four selected pins. As shown on the right of FIG. 16, the pin 1621 is short-circuited with the pin 1624, and the pin 1622 is short-circuited with the pin 1623.

In this example, detecting whether the four selected pins are effectively connected to the corresponding pins comprises detecting a voltage at the one of the four selected pins by the MCU, and determining whether the module is effectively connected to the backplane based on the detecting comprises determining the module is effectively connected to the backplane if the detected voltage is equal to zero, or determining the module is not effectively connected to the backplane if the detected voltage is equal to the voltage supplied by the power source.

Come back to FIG. 16. After the module 60 is connected to the backplane 160, a voltage at the pin 621 can be detected by the MCU 63.

On the one hand, if the selected pins 621-624 are effectively connected to the corresponding pins 1621-1624, a current will flow from the power source 64 to the ground in the following direction: the pin 621→the pin 1621→the pin 1624→the pin 624→the pin 623→the pin 1623→the pin 1622→the pin 622→ground. Only when all of the four selected pins 621-624 are connected to the corresponding pins 1621-1624, a circuit comprising the selected pins 621-624 and the corresponding pins 1621-1624 will be turned on, and a low level will be detected at the pin 621. So, the MCU 63 can determine the module 60 is effectively connected to the backplane 160 based on the low level, and thus determine the module 60 should be enabled. Therefore, the module 60 will have output/input values.

On the other hand, if any one of the four selected pins 621-624 is not effectively connected to the corresponding pin of the backplane 160, the circuit comprising the four selected pins 621-624 and the corresponding pins 1621-1624 will be turned off, and a high level will be detected at the pin 621. Thus, the MCU 63 can determine the module 60 is not effectively connected to the backplane 160 based on the high level, and thus determine the module 60 should not be enabled. Therefore, the module 60 will not have output/input values.

It should be understood that hereinbefore is described a specific example of the method for determining connection of a module with a backplane by way of example as shown in FIG. 16 and the present invention is not limited thereto. For example, although it is shown in FIG. 16 that the pin 621 of the four selected 621-624 is connected to the MCU 63 and a lower level can be detected at the pin 621 with the MCU 63 when the four selected 621-624 are effectively connected to the corresponding pins 1621-1625, it is possible that any one of the selected pins 623-624 can be connected to the MCU 63 and the lower level can be detected at any one of the selected pins 623-624 with the MCU 63 when the four selected 621-624 are effectively connected.

In another specific example according to the embodiment of the method of the present invention, the method further comprises: connecting one of the four selected pins to a power source via a first resister and to a MCU, connecting another one of the four selected pins to the ground, short-circuiting the remaining two of the four selected pins with each other, short-circuiting the pin of the second connector corresponding to the one of the four selected pins with the pin of the second connector corresponding to one of the remaining two of the four selected pins, and short-circuiting the pin of the second connector corresponding to the another one of the four selected pins with the pin of the second connector corresponding to the other of the remaining two of the four selected pins; wherein detecting whether the four selected pins are effectively connected to the corresponding pins comprises detecting a voltage at the one of the four selected pins with the MCU; and wherein determining whether the module is effectively connected to the backplane based on the detecting comprises determining the module is effectively connected to the backplane if the detected voltage is equal to zero, or determining the module is not effectively connected to the backplane if the detected voltage is equal to the voltage supplied by the power source. This specific example according to the embodiment of the method of the present invention may be implemented, for example, with the module 70 as shown in FIG. 7 and the corresponding backplane (not shown). Since this example is similar to the example as described with reference to FIG. 16, the detailed description thereof is omitted herein.

According to a fourth aspect of embodiments of the present invention, there is provided a system comprising a module supporting hot plug and a backplane. The module comprises a first connector comprising a first array of pins, and the backplane comprises a second connector comprising a second array of pins corresponding to the first array of pins. A portion of the pins of the first array are selected such that connection of the module with the backplane can be determined based on connection of the selected pins of the first array with corresponding pins of the second array.

According to an exemplary embodiment, the selected pins of the first array and the corresponding pins of the second array can be configured such that once the selected pins of the first array are effectively connected to the corresponding pins of the second array, the selected pins will come to be connected in series with each other, and a signal for indicating an effective connection of the selected pins with the corresponding pins of the second array can be detected at one terminal of the serial connection of the selected pins, whereby an effective connection of the module with the backplane can be determined based on the signal. More specifically, as an example only, one pin among the selected pins of the first array is connected a MCU while another one pin among the selected pins of the first array is grounded, and part of the remaining pins of the selected pins of the first array are short-circuited with each other. Meanwhile, part of the corresponding pins of the second array are short-circuited with each other in a way complementary with the short-circuited pins of the first array, so as to form a closed circuit when the selected pins of the first array are effectively connected to the corresponding pins of the second array. For example, the selected pins of the first array may comprise a first pair of pins and a second pair of pins and the corresponding pins of the second array may comprise a third pair of pins and a fourth pair of pins corresponding to the first pair of pins and the second pair of pins respectively. One of the second pair of pins is connected to a MCU while the other one of the second pair of pins is grounded, one of the first pair of pins is short-circuited with the other of the first pair of pins, and one of the third pair of pins is short-circuited with one of the fourth pair of pins and the other one of the third pair of pins is short-circuited with the other one of the fourth pair of pins.

According to an exemplary embodiment, the selected pins can comprise at least three pins which are located at or in close proximity to a periphery of the first array.

According to an exemplary embodiment, the selected pins can comprise at least four pins which are located at or in close proximity to an upper left corner, a lower left corner, a lower right corner and an upper right corner of the first array, respectively.

According to an exemplary embodiment, the selected pins can further comprise at least one pin which is located between the pins which are located at or in close proximity to the upper left and lower left corners of the first array, or between the pins which are located at or in close proximity to the lower right and upper right corners of the first array.

According to an exemplary embodiment, the system can further comprise a Micro Controller Unit (MCU) connected to the first connector and configured to determine, based on the determined connection of the module with the backplane, whether the module should be enabled. In this embodiment, one of the selected pins is connected to a power source via a first resister and to the MCU, and another one of the selected pins is connected to the ground. Alternatively, one of the selected pins is connected to the ground via a second resister and to the MCU, and another one of the selected pins is connected to a power source.

According to an exemplary embodiment, the system can further comprise a Micro Controller Unit (MCU) connected to the second connector. In this embodiment, one of the pins of the second array corresponding to the selected pins of the first array is connected to a power source via a third resister and to the MCU, and another one of the pins of the second array corresponding to the selected pins of the first array is connected to the ground. Alternatively, one of the pins of the second array corresponding to the selected pins of the first array is connected to the ground via a fourth resister and to the MCU, and another one of the pins of the second array corresponding to the selected pins of the first array is connected to a power source.

Finally, it should also be appreciated that the above description provides examples to describe the invention and to enable a person of ordinary skill in the art to make and use the invention. However, this above description is not intended to limit the invention to the precise terms set forth. Thus, while the invention has been described in detail with reference to the examples set forth above, those of ordinary skill in the art may made alterations, modifications and variations to the examples without departing from the scope of the invention.

1. A module supporting hot plug, comprising:
a connector for connecting the module to a backplane, the connector comprising:
an array of pins, wherein a portion of the pins of the array are selected such that connection of the module with the backplane can be determined based on connection of the selected pins with the backplane.

2. The module according to claim 1, wherein,
the selected pins are configured such that once the selected pins are effectively connected to the backplane, the selected pins will come to be connected in series with each other, and a signal for indicating an effective connection of the selected pins with the backplane can be detected at one terminal of a serial connection of the selected pins, whereby an effective connection of the module with the backplane can be determined based on the signal.

3. The module according to claim 2, wherein the selected pins comprises at least three pins which are located at or in close proximity to a periphery of the connector.

4. The module according to claim 2, wherein the selected pins comprises at least four pins which are located at or in close proximity to an upper left corner, a lower left corner, a lower right corner and an upper right corner of the array, respectively.

5. The module according to claim 2, further comprising:
a Micro Controller Unit (MCU) connected to the connector and configured to determine, based on the determined connection of the module with the backplane, whether the module should be enabled,
wherein one of the selected pins is connected to a power source via a first resister and to the MCU, and another one of the selected pins is connected to a ground, or
wherein one of the selected pins is connected to the ground via a second resister and to the MCU, and another one of the selected pins is connected to a power source.

6. A backplane, comprising:
a first connector being configured to be used in conjunction with a second connector of a module supporting hot plug, wherein the second connector comprises an array of pins, the first connector comprising:
an array of pins corresponding to the array of pins of the second connector,
wherein a portion of the pins of the array of the first connector are selected such that connection of the module with the backplane can be determined based on connection of the selected pins of the first connector with corresponding pins of the second connector.

7. The backplane according to claim 6, wherein,
the selected pins are configured such that once the selected pins are effectively connected to the corresponding pins of the second connector, the selected pins will come to be connected in series with each other, and a signal for indicating an effective connection of the selected pins with the corresponding pins of the second connector can be detected at one terminal of a serial connection of the selected pins, whereby an effective connection of the module with the backplane can be determined based on the signal.

8. The backplane according to claim 7, wherein the selected pins comprises at least three pins which are located at or in close proximity to a periphery of the first connector.

9. The backplane according to claim 7, wherein the selected pins comprises at least four pins which are located at or in close proximity to an upper left corner, a lower left corner, a lower right corner and an upper right corner of the array of the first connector, respectively.

10. The backplane according to claim 9, wherein the selected pins further comprises at least one pin which is located between the pins which are located at or in close proximity to the upper left and lower left corners, or between the pins which are located at or in close proximity to the lower right and upper right corners.

11. The backplane according to claim 7, further comprising:
a Micro Controller Unit (MCU) connected to the first connector,
wherein one of the selected pins is connected to a power source via a third resister and to the MCU, and another one of the selected pins is connected to a ground, or
wherein one of the selected pins is connected to the ground via a fourth resister and to the MCU, and another one of the selected pins is connected to a power source.

12. A system comprising a module supporting hot plug and a backplane, wherein the module comprises a first connector comprising a first array of pins, and the backplane comprises a second connector comprising a second array of pins corresponding to the first array of pins, and
wherein a portion of the pins of the first array are selected such that connection of the module with the backplane can be determined based on connection of the selected pins of the first array with corresponding pins of the second array.

13. The system according to claim 12, wherein
the selected pins of the first array and corresponding pins of the second array are configured such that once the selected pins of the first array are effectively connected to the corresponding pins of the second array, the selected pins will come to be connected in series with each other, and a signal for indicating an effective connection of the selected pins with the corresponding pins of the second array can be detected at one terminal of a serial connection of the selected pins, whereby an effective connection of the module with the backplane can be determined based on the signal.

14. The system according to claim 13, wherein the selected pins comprise at least three pins which are located at or in close proximity to a periphery of the first array.

15. The system according to claim 13, wherein the selected pins comprise at least four pins which are located at or in close proximity to an upper left corner, a lower left corner, a lower right corner and an upper right corner of the first array, respectively.

16. The system according to claim 15, wherein the selected pins further comprise at least one pin which is located between the pins which are located at or in close proximity to the upper left and lower left corners of the first array, or between the pins which are located at or in close proximity to the lower right and upper right corners of the first array.

17. The system according to claim 13, further comprising:
a Micro Controller Unit (MCU) connected to the first connector and configured to determine, based on the determined connection of the module with the backplane, whether the module should be enabled,
wherein one of the selected pins is connected to a power source via a first resister and to the MCU, and another one of the selected pins is connected to a ground, or
wherein one of the selected pins is connected to the ground via a second resister and to the MCU, and another one of the selected pins is connected to a power source.

18. The system according to claim 13, further comprising:
a Micro Controller Unit (MCU) connected to the second connector,
wherein one of the pins of the second array corresponding to the selected pins of the first array is connected to a power source via a third resister and to the MCU, and another one of the pins of the second array corresponding to the selected pins of the first array is connected to a ground, or
wherein one of the pins of the second array corresponding to the selected pins of the first array is connected to the ground via a fourth resister and to the MCU, and another one of the pins of the second array corresponding to the selected pins of the first array is connected to a power source.

19. The system according to claim 13, wherein the selected pins comprise a first pair of pins and a second pair of pins and the corresponding pins of the second array comprise a third pair of pins and a fourth pair of pins corresponding to the first pair of pins and the second pair of pins respectively, one of the first pair of pins is short-circuited with the other of the first pair of pins while one of the third pair of pins is short-circuited with one of the fourth pair of pins and the other one of the third pair of pins is short-circuited with the other one of the fourth pair of pins.

20. A method for determining connection of a module with a backplane, wherein the module comprises a first connector comprising an array of pins, and the backplane comprises a second connector comprising an array of pins corresponding to the array of pins of the first connector,
the method comprising:
selecting a portion of the pins of the first connector,
connecting the first connector to the second connector,
detecting whether the selected pins are effectively connected to corresponding pins of the second connector, and
determining whether the module is effectively connected to the backplane based on the detecting.

21. The method according to claim 20, further comprising:
configuring the selected pins such that once the selected pins are effectively connected to the backplane, the selected pins will come to be connected in series with each other, and a signal for indicating an effective connection of the selected pins with the backplane is detected at one terminal of a serial connection of the selected pins, whereby an effective connection of the module with the backplane is determined based on the signal.

22. The method according to claim 20, wherein selecting a portion of the pins of the first connector comprises selecting at least three pins which are located at or in close proximity to a periphery of the first connector.

23. The method according to claim 20, wherein selecting a portion of the pins of the first connector comprises selecting at least four pins which are located at or in close proximity to an upper left corner, a lower left corner, a lower right corner and an upper right corner of the first connector, respectively.

24. The method according to claim 23, further comprising:
connecting one of the four selected pins to a power source via a first resister and to a MCU,
connecting another one of the four selected pins to a ground,
short-circuiting the remaining two of the four selected pins with each other,
short-circuiting the pin of the second connector corresponding to the one of the four selected pins with the pin of the second connector corresponding to one of the remaining two of the four selected pins, and
short-circuiting the pin of the second connector corresponding to the another one of the four selected pins with the pin of the second connector corresponding to the other of the remaining two of the four selected pins;
wherein detecting whether the four selected pins are effectively connected to the corresponding pins comprises detecting a voltage at the one of the four selected pins with the MCU; and
wherein determining whether the module is effectively connected to the backplane based on the detecting comprises determining the module is effectively connected to the backplane if the detected voltage is equal to zero, or determining the module is not effectively connected to the backplane if the detected voltage is equal to the voltage supplied by the power source.

25. The method according to claim 23, further comprising:
connecting one of the four selected pins to a ground via a second resister and to a MCU,
connecting another one of the four selected pins to a power source,
short-circuiting the remaining two of the four selected pins with each other,
short-circuiting the pin of the second connector corresponding to the one of the four selected pins with the pin of the second connector corresponding to one of the remaining two of the four selected pins,
short-circuiting the pin of the second connector corresponding to the another one of the four selected pins with the other of the remaining two of the four selected pins;
wherein detecting whether the four selected pins are effectively connected to the corresponding pins of the second connector comprises detecting a voltage at the one of the four selected pins with the MCU; and
wherein determining whether the module is effectively connected to the backplane based on the detecting comprises determining the module is effectively connected to the backplane if the detected voltage is equal to the voltage supplied by the power source, or determining the module is not effectively connected to the backplane if the detected voltage is equal to zero.
